(19) United States
(12) Patent Application Publication
(10) Pub. No.: US 2026/0305493 A1
(43) Pub. Date: Oct. 1, 2026

(54) SEMICONDUCTOR DEVICE WITH SUPPLEMENTAL CIRCUITS FORMED IN RESERVED REGION

(71) Applicant: AP MEMORY TECHNOLOGY CORPORATION, Zhubei City (TW)

(72) Inventors: Wenliang CHEN, Zhubei City (TW); Jian-Jhang HUANG, Zhubei City (TW)

(73) Assignee: AP MEMORY TECHNOLOGY CORPORATION, Zhubei City (TW)

(21) Appl. No.: 19/441,112

(22) Filed: Jan. 6, 2026

Related U.S. Application Data
(60) Provisional application No. 63/777,986, filed on Mar. 26, 2025.

(51) Int. Cl. H10W 90/20; H10B 80/00; H10D 80/30; H10W 90/00

(52) U.S. Cl. CPC H10W 90/297; H10B 80/00; H10D 80/30; H10W 90/792

(57) ABSTRACT

A semiconductor device includes a first memory tier and a second memory tier. The first memory tier includes a first array region having a first memory cell formed therein, and a first reserved region laterally adjacent to the first array region. The first memory tier further includes a vertical connector formed in the first reserved region and electrically coupled to the first memory cell. The second memory tier is disposed on the first memory tier, and includes a second array region having a second memory cell formed therein, and a second reserved region laterally adjacent to the second array region. The second memory tier further includes supplemental circuits formed in the second reserved region. The vertical connector extends vertically through the first memory tier. The second reserved region of the second memory tier overlaps the first reserved region of the first memory tier.

### CROSS REFERENCE TO RELATED APPLICATIONS

This application claims the benefit of U.S. provisional application No. 63/777,986 filed Mar. 26, 2025, the entirety of which is incorporated by reference herein.

### TECHNICAL FIELD

The present disclosure relates to semiconductor technology, and in particular to a semiconductor device with supplemental circuits formed in the reserved region that is capable of enhancing the efficiency of spatial utilization.

### BACKGROUND

Semiconductor packaging refers to the process of enclosing a semiconductor device in a protective casing to protect it from external damage and to facilitate its integration into electronic systems.

Heterogeneous integration allows semiconductor companies to combine chiplets with diverse functions so that the resulting assembly operates as a single product. The demand for transistors in applications such as high-performance computing and artificial intelligence continues to increase at an exponential rate, while the ability to shrink transistors with classic 2D scaling is slowing and becoming more expensive. In some comparative embodiments, chip makers might integrate chiplets into advanced 2.5D and 3D packages structures using through-substrate vias (TSVs) and/or hybrid bonding. Through-substrate vias allow designers to increase levels of performance and reduce power consumption, compared to the approach of having a legacy chip on a printed circuit board (PCB).

### BRIEF SUMMARY

In some embodiments, a semiconductor device is provided. The semiconductor device includes a first memory tier and a second memory tier. The first memory tier includes a first array region having a first memory cell, and a first reserved region laterally adjacent to the first array region. The first memory tier further includes a vertical connector formed in the first reserved region and electrically coupled to the first memory cell. The second memory tier is disposed on the first memory tier, and includes a second array region having a second memory cell, and a second reserved region laterally adjacent to the second array region. The second memory tier further includes supplemental circuits formed in the second reserved region. The vertical connector extends vertically through the first reserved region. The second reserved region of the second memory tier overlaps the first reserved region of the first memory tier.

In some embodiments, a semiconductor device is provided. The semiconductor device includes a bottom logic die, a middle memory tier, and a top memory tier. The middle memory tier is stacked over the bottom logic die and includes a plurality of first memory dies stacked on each other. Each of the plurality of first memory dies includes a first array region having a plurality of first memory cells and a first reserved region laterally adjacent to the first array region. The top memory tier is stacked over the middle memory tier and includes a top memory die. The top memory die includes a top array region and a top reserved region laterally adjacent to the top array region. The top reserved region includes a plurality of supplemental circuits and overlaps the first reserved regions of the plurality of first memory dies. The middle memory tier further includes a plurality of vertical connectors extending vertically through the first reserved regions of the plurality of first memory dies.

### BRIEF DESCRIPTION OF THE DRAWINGS

Aspects of the present disclosure are best understood from the following detailed description when read with the accompanying figures. It is noted that, in accordance with the standard practice in the industry, various structures are not drawn to scale. In fact, the dimensions of the various structures may be arbitrarily increased or reduced for clarity of discussion.

FIG. 1 shows a cross-sectional view of a semiconductor device with supplemental circuits in accordance with some embodiments.

FIG. 2A shows an enlarged partial view of the semiconductor device of FIG. 1 in accordance with some embodiments.

FIG. 2B shows an alternative example of FIG. 2A in accordance with some embodiments.

FIG. 3A shows an enlarged partial view of a semiconductor device with supplemental circuits in accordance with some embodiments.

FIG. 3B shows an alternative example of FIG. 3A in accordance with some embodiments.

FIG. 4A shows an enlarged partial view of a semiconductor device with supplemental circuits in accordance with some embodiments.

FIG. 4B shows an alternative example of FIG. 4A in accordance with some embodiments.

FIG. 5 shows a cross-sectional view of a semiconductor device in accordance with some embodiments.

FIGS. 6A to 6E are schematic diagrams illustrating various stages of a method for manufacturing a semiconductor device in accordance with some embodiments.

### DETAILED DESCRIPTION

The making and using of the embodiments of the present disclosure are discussed in detail below. However, it should be noted that the embodiments provide many applicable inventive concepts that can be embodied in a variety of specific methods. The specific embodiments discussed are merely illustrative of specific methods to make and use the embodiments, and do not limit the scope of the disclosure. In addition, the present disclosure may repeat reference numbers and/or letters in the various embodiments. This repetition is for the purpose of simplicity and clarity, and does not imply any relationship between the different embodiments and/or configurations discussed. The scope of the disclosure is best determined by reference to the appended claims.

In the following descriptions, terms “about” and “substantially” typically mean +/- 10% of the stated value, or typically +/- 5% of the stated value, or typically +/- 3% of the stated value, or typically +/- 2% of the stated value, or typically +/- 1% of the stated value or typically +/- 0.5% of the stated value. The expression “in a range from the first value to the second value” or “between the first value and the second value” means that the range includes the first value, the second value, and other values in between. The values given in the present disclosure are approximate. That is, without specifying terms the terms “about” and “substantially,” the meaning of “about” and “substantially” can still be implied.

Further, spatially relative terms, such as “beneath,” “below,” “lower,” “above,” “upper,” “on” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the terms such as “first”, “second” and “third” describe various elements, components, regions, layers and/or sections, these elements, components, regions, layers and/or sections should not be limited by these terms. These terms may be only used to distinguish one element, component, region, layer, or section from another. The terms such as “first”, “second”, and “third” when used herein do not imply a sequence or order unless clearly indicated by the context.

In 3DIC stacking technology today, in stacked semiconductor dies/wafers, each die/wafer typically includes a reserved region for forming vertical connectors, such as TSV for providing vertical connections between the stacked semiconductor dies/wafers. These vertical connectors in the reserved region ensure vertical signal and power delivery across tiers. As used herein, the term “tier” refers to one or more individual semiconductor dies or one or more wafers in a vertically stacked semiconductor device. Conventionally, the reserved region in the top tier is unused (e.g. no active/passive components formed therein), since there are no needs to form vertical connectors therein (if there is no another tier disposed above). According to the present invention, a semiconductor device including stacked semiconductor tiers having improved spatial utilization and/or sufficient layout efficiency is provided for advanced integrated circuit architectures so that no unused spatial regions remain in a semiconductor device.

In some embodiments of the present disclosure, supplemental circuits are formed in the reserved region of the top tier, thereby improving the spatial utilization of the top semiconductor die/wafer. The supplemental circuits may also be shared with the adjacent semiconductor die/wafer, since these circuits are disposed in proximity to the reserved region of the adjacent tier.

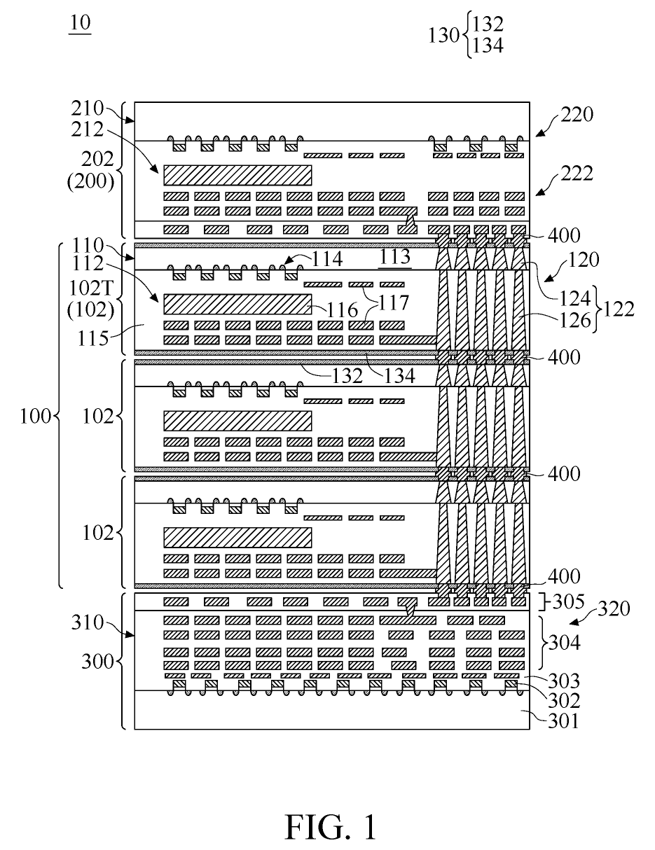

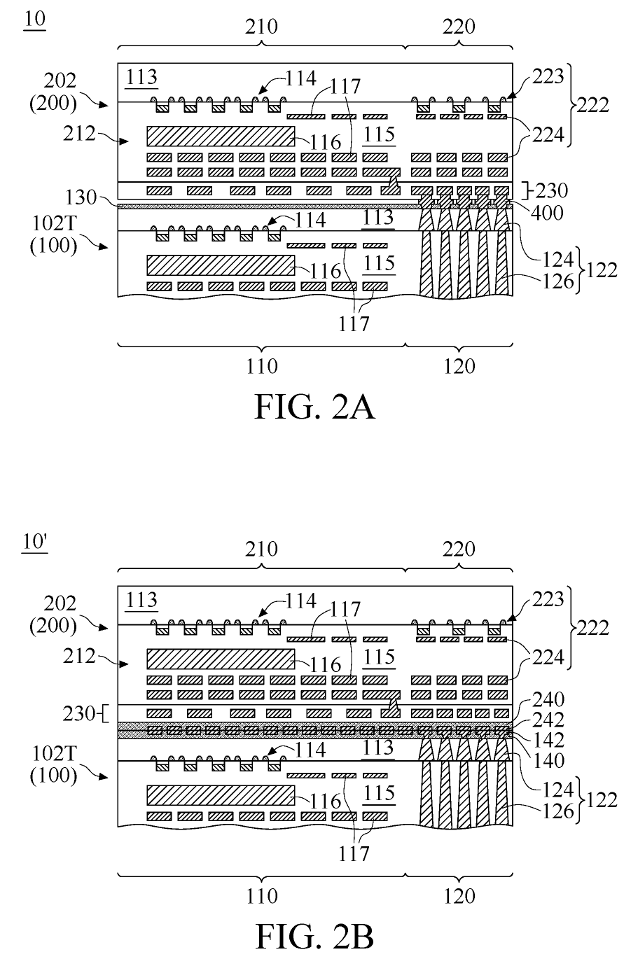

FIG. 1 shows a cross-sectional view of a semiconductor device 10 with supplemental circuits 222 in accordance with some embodiments. FIG. 2A shows an enlarged partial view of the semiconductor device 10 of FIG. 1 in accordance with some embodiments.

As shown in FIG. 1, the semiconductor device 10 includes a first memory tier 100 and a second memory tier 200 disposed on the first memory tier 100. The first memory tier 100 includes vertical connectors 122, and the second memory tier 200 includes supplemental circuits 222, which will be described in detail hereinafter.

In some embodiments, the semiconductor device 10 also includes a bottom logic die 300 below the first memory tier 100. The first memory tier 100 is stacked over the bottom logic die 300, and the second memory tier 200 is stacked over the first memory tier 100. For example, the semiconductor device 10 includes a stacked structure having the bottom logic die 300, the first memory tier 100 (can be also referred to as the middle memory tier in some embodiments), and the second memory tier 200 (can be also referred to as the top memory tier in some embodiments) sequentially disposed over one another. In some embodiments, the first and the second memory tiers 100 and 200 are memory devices which provide storage capacity, while the bottom logic die 300 provides control signals and processing functions.

In some embodiments, the first memory tier 100 and the second memory tier 200 (or the bottom logic die 300) are bonded through conductive connectors. As shown in FIG. 1, the semiconductor device 10 further includes conductive connectors 400 formed between the bottom logic die 300, the first memory tier 100, and the second memory tier 200 in the reserved region. In an embodiment, the conductive connectors 400 are solder bumps. In some embodiments, the conductive connectors 400 are pillars that include Cu, Ag, Au, Ni, Ti, or a combination thereof. The conductive connectors 400 are employed to provide bonding between the bottom logic die 300, the first memory tier 100, and the second memory tier 200.

The semiconductor device 10 includes an array region in which one or more active components are formed, and a reserved region in which one or more vertical connectors are formed. Each of the bottom logic die 300, the first memory tier 100, and the second memory tier 200 includes an array region and a reserved region, which will be described in detail hereinafter. These array regions are aligned with one another along, for example, a stacking direction, and likewise, those reserved regions are also aligned with one another. For example, these array regions may overlap each other in a plan view.

The first memory tier 100 may include a plurality of first memory dies 102 stacked on one another. Each of the first memory dies 102 includes a respective first array region 110 and a respective first reserved region 120 laterally adjacent to the first array region 110. In other words, the respective first array region 110 and the respective first reserved region 120 of each first memory die 102 correspond to the array region and the reserved region of the first memory tier 100, respectively.

A plurality of first memory cells 112 is formed in the first array regions 110. Each of the first memory cells 112 includes, for example, a front-end-of-line (FEOL) structure and/or a middle-end-of-line (MEOL) structure, in which semiconductor devices such as active components 114 (e.g., transistors) and/or passive components 116 (e.g., capacitors and/or inductors) are formed or embedded.

In some embodiments, the first memory cell 112 includes a substrate 113, the active components 114 formed on the substrate 113, a dielectric layer 115 disposed over the substrate 113, and the passive components 116 and a metallization structure 117 embedded in the dielectric layer 115. Typically, the active components 114 are formed adjacent to the front side surface of the substrate 113. The metallization structure 117 is electrically coupled to the active components 114 and includes one or more stacks of metal layers (e.g., M1, M2…, Mx) and one or more conductive vias (not shown) in the dielectric layer 115. Those metal layers, can be referred as MEOL and/or back-end-of-line (BEOL), in each stack are vertically arranged and electrically coupled to each other by the conductive vias between two adjacent metal layers. The first memory cell 112 may adopt the same materials and configurations as existing memory, such as dynamic-random-access-memory (DRAM), and a detailed description thereof is omitted herein for brevity.

In some embodiments, one or more vertical connectors 122 are formed in the first reserved region 120 and electrically coupled to the first memory cell 112. The vertical connectors 122 may be electrically coupled to the metallization structure 117 of the first memory cell 112. The vertical connectors 122 in the first reserved region 120 may extend vertically through the first memory die 102 (102T) along the stacking direction. In some embodiments, the vertical connectors 122 are arranged side by side along a direction different from the stacking direction, for example, a direction perpendicular to the stacking direction. These vertical connectors 122 can deliver signals and power vertically within the same memory tier and/or between adjacent memory tiers. For example, the vertical connectors 122 are configured to transmit signal and power between the first memory cells 112 of different first memory dies 102 in the first memory tier 100. In some embodiments, the vertical connectors 122 electrically couple the first memory cells 112 of the first memory tier 100 to the bottom logic die 300.

The vertical connectors 122 may include a TSV 124, a through-dielectric via (TDV) 126, or a combination thereof. As shown in FIG. 1, each of the vertical connectors 122 includes the TSV 124 and the TDV 126 connected and extended along the stacking direction. In some embodiments, the TSV 124 penetrates through the substrate 113 (e.g., silicon) of the first memory die 102, while the TDV 126 penetrates through the dielectric layer 115 (e.g., interlayer dielectric such as silicon oxide, low-k dielectrics, and the like) of the first memory die 102.

In some embodiments, passivation layers 130 are respectively disposed on opposite surfaces of the first memory die 102. For example, the passivation layers 130 includes a first passivation layer 132 and a second passivation layer 134. The first passivation layer 132 is disposed on a surface of the substrate 113 opposite to the active components 114, and the second passivation layer 134 is disposed on a surface of the dielectric layer 115 opposite to the substrate 113. The passivation layers 130 include openings, and the conductive connectors 400 are formed in the openings. In some embodiments, the vertical connectors 122 are electrically coupled to the conductive connectors 400 disposed at opposite sides of the first memory die 102. For example, the TSV 124 is electrically coupled to the conductive connectors 400 disposed on the substrate 113 side, and the TDV 126 is electrically coupled to the conductive connectors 400 disposed on the dielectric layer 115 side.

The bottom logic die 300 includes a first region 310 disposed below the first array region 110 of the first memory tier 100, and a second region 320 disposed below the first reserved region 120 of the first memory tier 100. In some embodiments, the first region 310 is vertically aligned with the first array region 110, and the second region 320 is vertically aligned with the first reserved region 120. In some embodiments, the first region 310 is an active region, and the second region 320 is a peripheral region.

In some embodiments, the bottom logic die 300 includes a machine learning processor or a deep learning processor that contains one or more active components 302 (e.g., transistors) formed in the first region 310. In some other embodiments, the active components 302 in the bottom logic die 300 may be the transistors to control or to switch the advanced memory device, such as, but not limited to, the switch transistors for advanced dynamic-random-access-memory (DRAM) or high-bandwidth memory (HBM). For example, the bottom logic die 300 may be used to control and/or switch the memory devices in the first memory tier 100.

In some embodiments, the bottom logic die 300 includes a substrate 301, the active components 302 formed on the substrate 301, a dielectric layer 303 disposed over the substrate 301, a metallization structure 304 having a plurality of metal layers (e.g., M1, M2…, Mx) embedded in the dielectric layer 303, and a redistribution layer (RDL) 305 disposed over the dielectric layer 303. The metal layer of the RDL 305 is electrically coupled to the metallization structure 304. In some embodiments, the conductive connectors 400 are formed between, and electrically coupled to, the RDL 305 and the vertical connectors 122. Accordingly, the bottom logic die 300 is electrically connected to the first memory dies 102 through the conductive connectors 400 and the vertical connectors 122.

The second memory tier 200 includes a second memory die 202 (also referred to as a top memory die). The second memory die 202 is stacked over the topmost of the first memory dies 102 (also referred to as a topmost first memory die 102T). In some embodiments, the second memory die 202 and the topmost first memory die 102T are bonded through the conductive connectors 400.

The second memory die 202 includes a second array region 210 (also referred to as top array region) and a second reserved region 220 (also referred to as top reserved region) laterally adjacent to the second array region 210. In some embodiments, the second memory die 202 is a single die without stacking. When viewed from the top of the semiconductor device 10, the second array region 210 overlaps the first array region 110 of the first memory dies 102, and the second reserved region 220 overlaps the first reserved regions 120 of the first memory dies 102. In some embodiments, the second array region 210 is superimposed on (or vertically aligned with) the first array region 110, and the second reserved region 220 is superimposed on the first reserved region 120.

As shown in FIG. 1, the second reserved region 220 of the second memory tier 200 is also vertically aligned with the second region 320 of the bottom logic die 300. In some embodiments, the vertical connectors 122 are interposed between the second region 320 of the bottom logic die 300 and the second reserved region 220 of the second memory tier 200. The second memory tier 200 and the bottom logic die 300 may be electrically coupled to each other through the vertical connectors 122.

A second memory cell 212 (also referred to as top memory cell) is formed in the second array region 210. In some embodiments, the second memory cell 212 and the first memory cells 112 of the first memory dies 102 are both DRAM cells. The second memory cell 212 may have a structure and configuration similar to those of the first memory cells 112, and a detailed description thereof is omitted herein for the sake of brevity. The second memory cell 212 may be produced using substantially the same process as the first memory cells 112.

In some embodiments, a redistribution layer (RDL) 230 is disposed over the dielectric layer 115 of the second memory cell 212. The RDL 230 is electrically coupled to the metallization structure 117 in the second memory cell 212 and the conductive connectors 400.

In some embodiments, one or more supplemental circuits 222 are formed in the second reserved region 220. The supplemental circuits 222 in the second reserved region 220 are electrically coupled to the vertical connectors 122 in the first reserved regions 120 through the conductive connectors 400.

In some embodiments, the plurality of first memory dies 102 may be produced using substantially the same semiconductor manufacturing process, while the second memory die 202 may be produced using a process different from that of the first memory dies 102. For example, the plurality of first memory dies 102 is fabricated using a first reticle set (not shown), and the second memory die 202 is fabricated using a second reticle set (not shown) different from the first reticle set. For example, the first memory dies 102, which share the first reticle set, have vertical connectors 122 formed within the first reserved region 120, whereas the second memory die 202 is patterned with the second reticle set so that the second reserved region 220 can include the supplemental circuits 222. As a result, design flexibility is provided in the second reserved region 220 of the second memory die 202. The second reserved region 220 may include the supplemental circuits 222 rather than being reserved solely for vertical connectors. The supplemental circuits 222 may include, without limitation, power management circuits, capacitors, or supplemental memory cells. Accordingly, the supplemental circuits 222 enable effective and flexible utilization of the second reserved region 220 in the second memory tier 200, thereby providing various functions (see detailed discussions below) and reducing manufacturing cost by reducing or avoiding the use of extra functional dies whose functions can be provided by the supplemental circuits 222.

Because of their proximity to the vertical connectors 122, the supplemental circuits 222 may serve as common circuits shared by all memory tiers, including the first memory tiers 100 and the second memory tier 200. For example, both the first memory cells 112 and the second memory cell 212 are electrically connected to the supplemental circuits 222.

In some embodiments, the supplemental circuits 222 may include peripheral circuits or application-specific integrated circuits (ASICs). The supplemental circuits 222 may be, without limitation, power management circuits, TSV encoder/decoder circuits, global charge pump circuits, or control circuits. As used herein, “global” may refer to “common” or “shared.” For example, each tier may share charge pump circuits, and in some embodiments, may share power management circuits, TSV encoder/decoder circuits, or control circuits. In some embodiments, the supplemental circuits 222 are power management circuits configured to regulate or convert power delivered through the vertical connectors 122. In other embodiments, the supplemental circuits 222 are control circuits configured to control the signals transmitted through the plurality of vertical connectors 122.

The supplemental circuits 222 include one or more active components 223 (e.g., transistors) together with a metallization structure 224, thereby enabling circuit functionalities such as regulation, switching, or control, in accordance with some embodiments. The active components 223 and the metallization structure 224 may be designed to be the same as, or compatible with, the processes used for the active components 114 and the metallization structure 117 of the second memory cell 212, respectively. For example, the active components 223 may be fabricated by the same process node as the active components 114, and the metallization structure 224 may be fabricated by the same process node as the metallization structure 117. In some exemplary embodiments, the second memory cell 212 in the second array region 210 includes DRAM switch transistors, DRAM capacitors electrically coupled to the DRAM switch transistors, and DRAM periphery transistors. The supplemental circuits 222 of the second reserved region 220 include additional transistors (such as the active components 223) fabricated by the same process node as the DRAM periphery transistors. In some embodiments, the metallization structure 224 may cooperate with the RDL 230 to distribute regulated power to the first memory cells 112 of the first memory dies 102 and to the second memory cell 212 of the second memory die 202.

In FIGS. 1 and 2A, the memory tiers are bonded to one another through the conductive connectors 400. In some embodiments, the first memory tier 100 and the second memory tier 200 (or the bottom logic die 300) are bonded through a hybrid bonding structure, as illustrated in FIG. 2B.

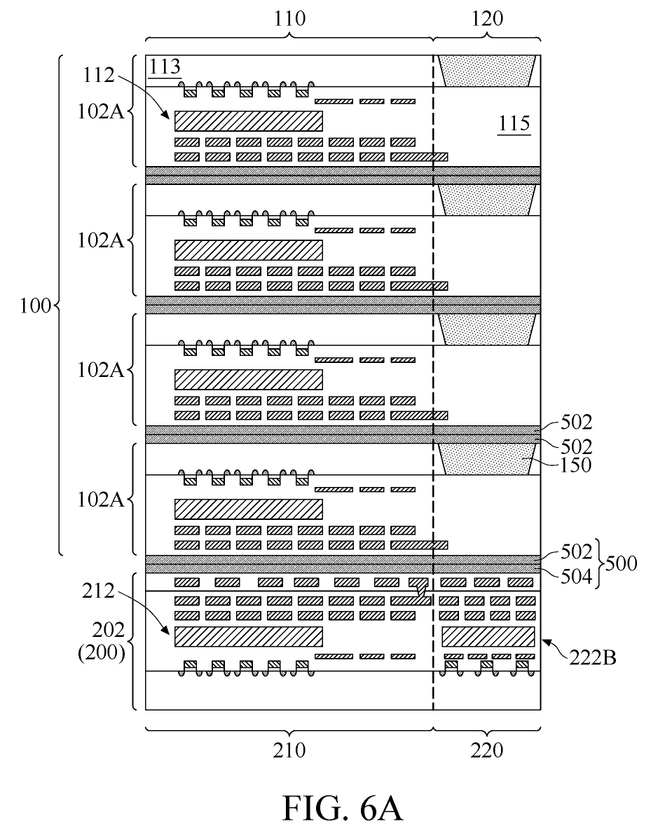

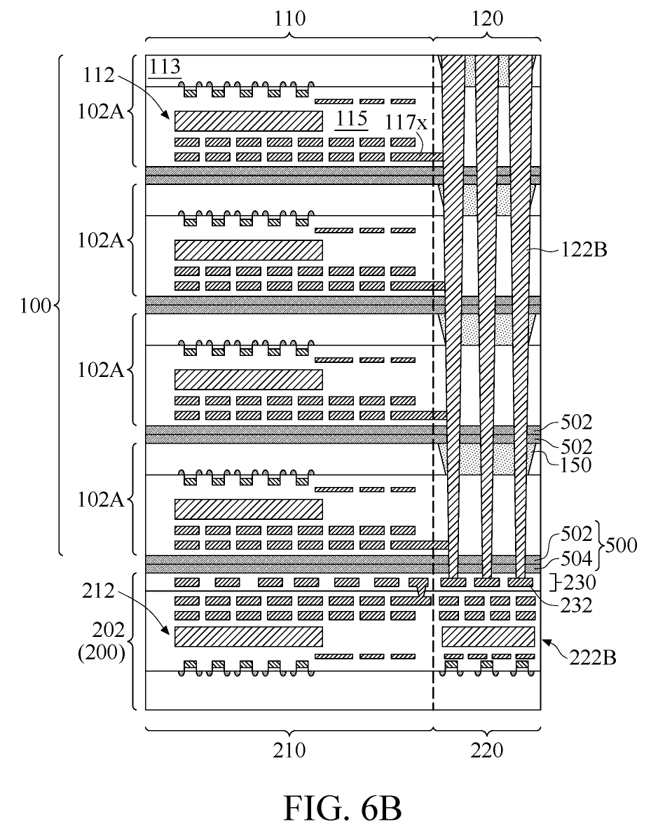

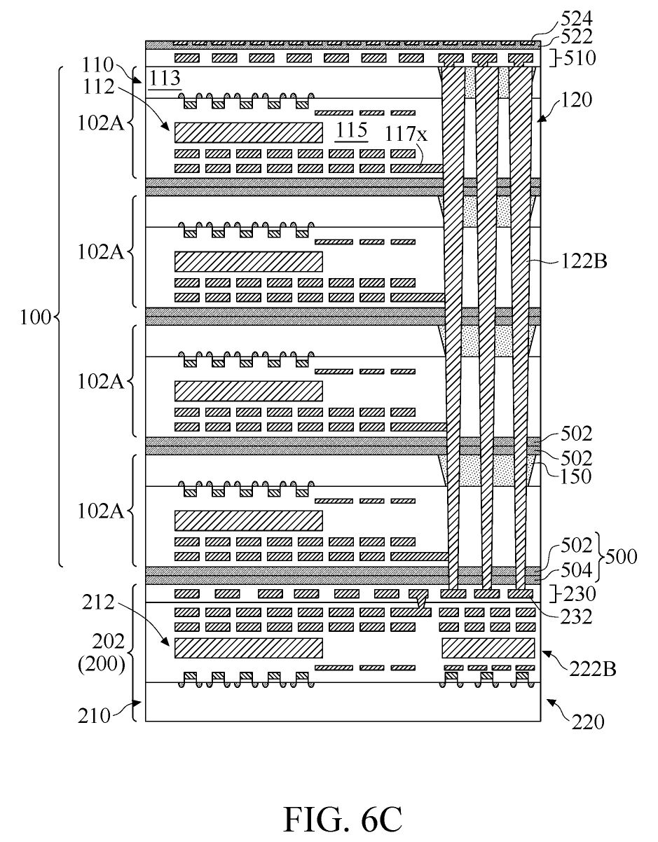

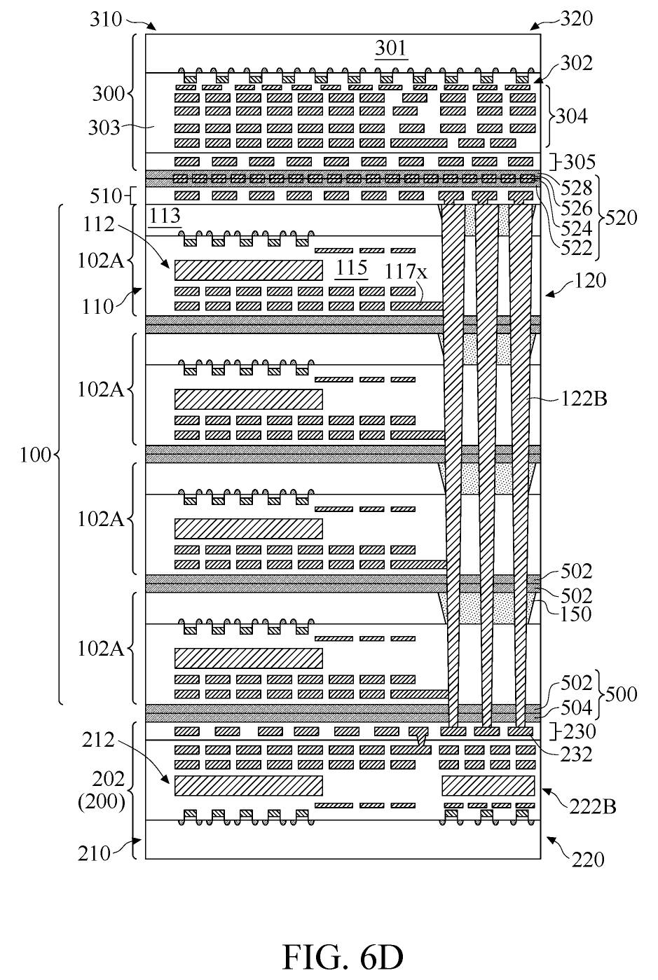

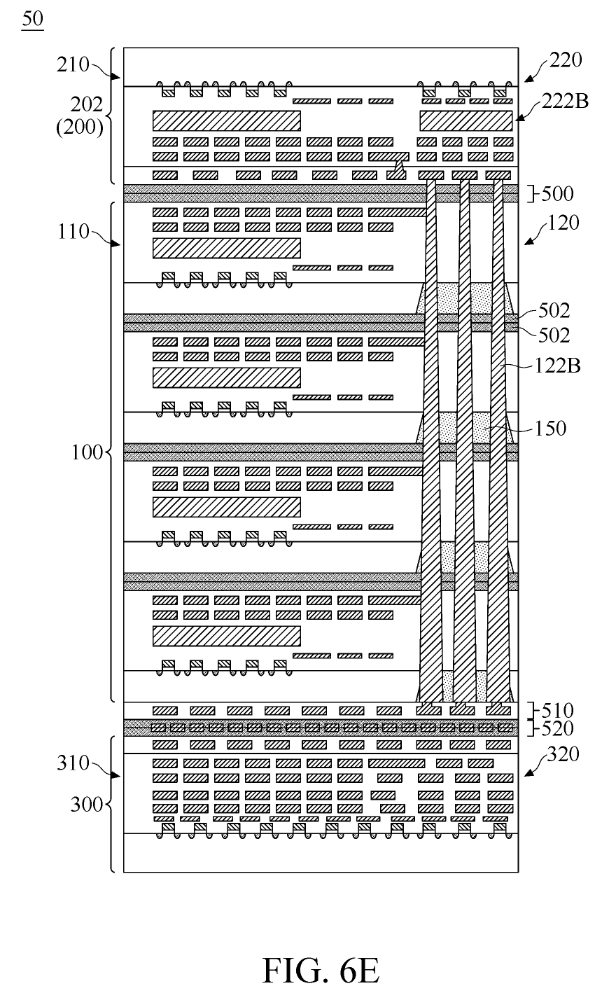

FIG. 2B shows an enlarged partial view of a semiconductor device 10’ in accordance with some embodiments. In some embodiments, the first memory tier 100 is bonded to the second memory tier 200 by a hybrid bonding process, so as to form a hybrid bonding interface between the topmost first memory die 102T and the second memory die 202. In some embodiments, the first memory tier 100 is further bonded to the bottom logic die 300 by the hybrid bonding process, which will be described with reference to FIG. 6E. The hybrid bonding involves at least two types of bonding, including metal-to-metal bonding structure and non-metal-to-non-metal bonding structure (e.g., dielectric-to-dielectric bonding structure).

In some embodiments, a first insulating layer 140 is formed over the backside surface of the substrate 113 of the topmost first memory die 102T. A plurality of first bonding pads 142 is formed within, and exposed through, the first insulating layer 140. In addition, a second insulating layer 240 is formed over a surface of the RDL 230 of the second memory die 202, with a plurality of second bonding pads 242 exposed therethrough. In such hybrid bonding cases, the metal-to-metal bonding involves the first bonding pads 142 in direct contact with the second bonding pads 242. Moreover, the dielectric-to-dielectric bonding involves the first insulating layer 140 covalently bonded to the second insulating layer 240. The bonding process is not limited to the foregoing examples, and other suitable bonding methods may also be applied.

In FIGS. 1, 2A, and 2B, power management circuits are illustrated as an example of the supplemental circuits 222. In other embodiments, the supplemental circuits 222 may include passive components (e.g., capacitors and/or inductors) only and without transistors.

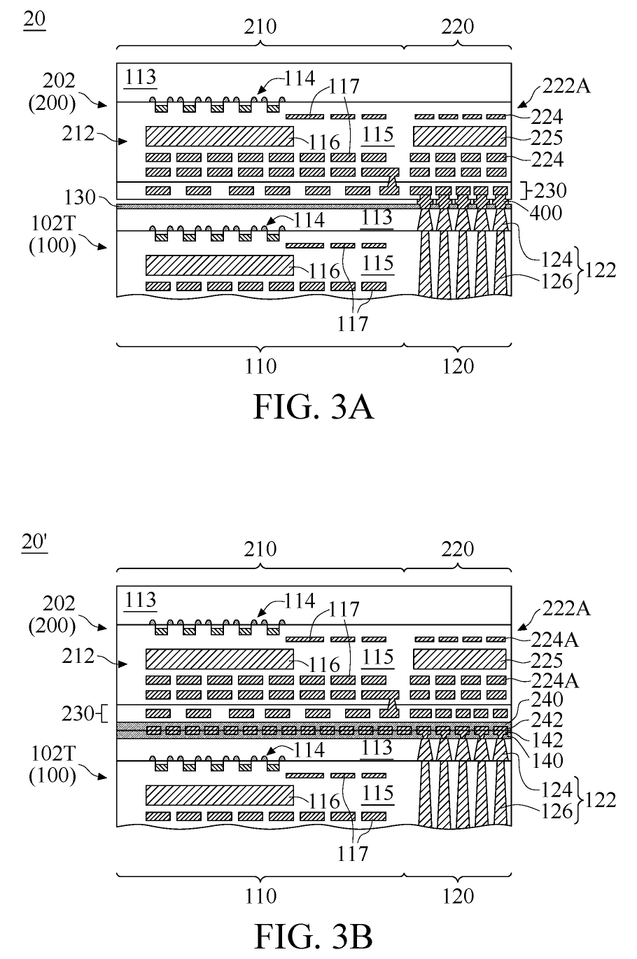

FIG. 3A shows an enlarged partial view of the semiconductor device 20 in accordance with some embodiments. Elements in FIG. 3A that are similar to those in FIGS. 1 and 2A are labeled with the same reference numbers as in FIGS. 1 and 2A and may not be described again. In some embodiments, the semiconductor device 20 shown in FIG. 3A is similar to the semiconductor device 10 shown in FIGS. 1 and 2A. However, the supplemental circuits 222A of the semiconductor device 20 has a configuration and/or structure different than that of the supplemental circuits 222 of the semiconductor device 10.

As shown in FIG. 3A, the supplemental circuits 222A include the metallization structure 224 and a passive component 225 (e.g., capacitors and/or inductors) formed in the dielectric layer 115. The passive component 225 may be formed between the metal layers of the metallization structure 224, and may have the same or substantially similar process and/or structure as the passive components 116 in the second memory cell 212. In some embodiments, the supplemental circuits 222A are free or substantially free of the active components.

In some embodiments, the passive component 225 may function as a decoupling capacitor or as a capacitor for voltage regulators or voltage converters, thereby contributing to power regulation of the semiconductor device 20. In conventional semiconductor devices, such capacitors are typically formed in a logic die or an additional die. However, by forming the passive component 225 in the 22022 220 of the second memory tier 200, the passive component 225 in the second reserved region 220 can be integrated with the passive components 116 of the second memory cell 212 in the second array region 210 of the second memory tier 200 so that an additional space or another individual die for providing the same functions of the passive component 225 can be saved.

FIG. 3B shows an alternative example of FIG. 3A in accordance with some embodiments. In semiconductor device 20 shown in FIG. 3A, conductive connectors 400 are used to electrically couple the tiers 100 and 200, whereas in semiconductor device 20’ shown in FIG. 3B, hybrid bonding is employed. The hybrid bonding structures or processes may adopt the same or substantially similar configurations as illustrated in FIG. 2B. For example, the first memory tiers 100 and the second memory tier 200 may be bonded using metal-to-metal bonding between the bonding pads 142 and 242, and dielectric-to-dielectric bonding between the insulating layers 140 and 240.

In further embodiments, the supplemental circuits 222 may alternatively be additional memory cells, such as DRAM cells that are not electrically connected to the first memory cell in the first array region of the first memory tier and the second memory cell in the second array region of the second memory tier.

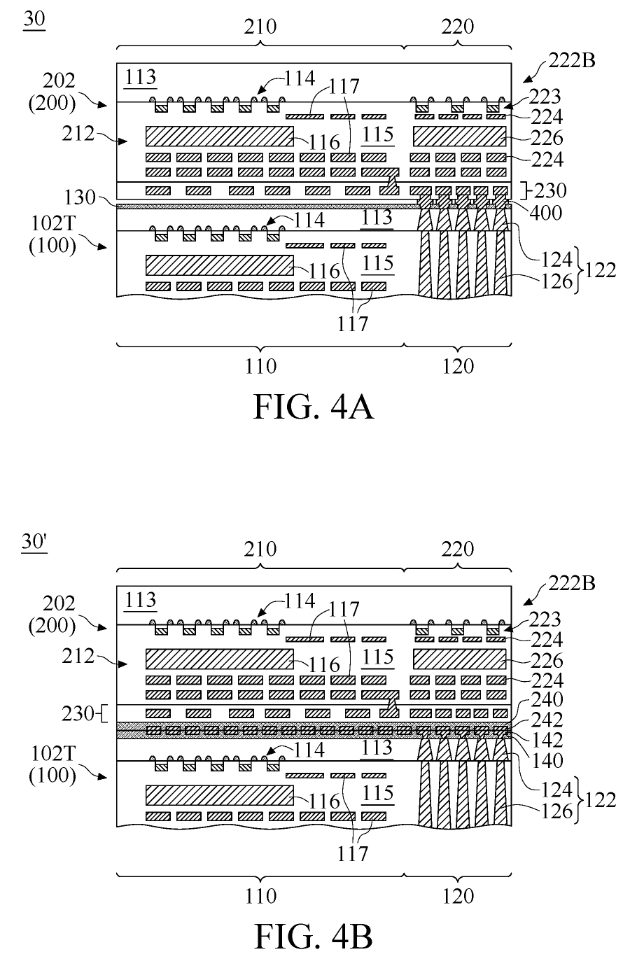

FIG. 4A shows an enlarged partial view of the semiconductor device 30 in accordance with some embodiments. Elements in FIG. 4A that are similar to those in FIGS. 1 and 2A are labeled with the same reference numbers as in FIGS. 1 and 2A and may not be described again. In some embodiments, the semiconductor device 30 shown in FIG. 4A is similar to the semiconductor device 10 shown in FIGS. 1 and 2A. However, the supplemental circuits 222B of the semiconductor device 30 has a configuration and/or structure different than that of the supplemental circuits 222 of the semiconductor device 10.

As shown in FIG. 4A, the supplemental circuits 222B include DRAM cells having active components 223 (e.g., transistors), the metallization structure 224 and a passive component 226 (e.g., capacitors and/or inductors). The supplemental circuits 222B may have a structure and configuration similar to those of the first memory cell 112 and/or second memory cell 212. For example, the supplemental circuits 222B in the second reserved region 220 may include DRAM switch transistors, DRAM capacitors electrically coupled to the DRAM switch transistors, and DRAM periphery transistors. The supplemental circuits 222B may be fabricated by the same process node as the second memory cell 212 in the second array region 210.

In some embodiments, the supplemental circuits 222B are employed as redundant memory cells for repairing or replacing defective memory cells in the array region. Accordingly, when a memory cell in the array region (such as the first memory cell 112 and/or the second memory cell 212) is damaged, the supplemental circuits 222B may be activated for repair purposes. In some embodiments, there are some circuits (e.g., circuits including fuses or programmable switches) that bridge the memory cell in the array region and the redundant memory cells in the supplemental circuits 222B, and the supplemental circuits 222B can be electrically coupled to the memory cell in the array region by selectively enabling the bridging circuits, for example by programming the fuses to disconnect the defective memory cell and connect a corresponding redundant memory cell for normal operation.

In some embodiments, the supplemental circuits 222B are configured to store at least one information using for error correction, error detection, or repairing operation. The information incudes error-correction code (ECC) data or a repair table. Conventionally, to have such information storage in a semiconductor device require sacrificing a portion of the array region and/or needing an individual DRAM die, both of which increase design complexity and overall manufacturing cost. In contrast, according to the present disclosure, the supplemental circuits 222B may be formed in the reserved region, thereby avoiding the loss of array capacity and/or reducing overall manufacturing cost.

FIG. 4B shows an alternative example of FIG. 4A in accordance with some embodiments. In semiconductor device 30 shown in FIG. 4A, conductive connectors 400 are used to electrically couple the tiers 100 and 200, whereas in semiconductor device 30’ shown in FIG. 4B, hybrid bonding is employed.

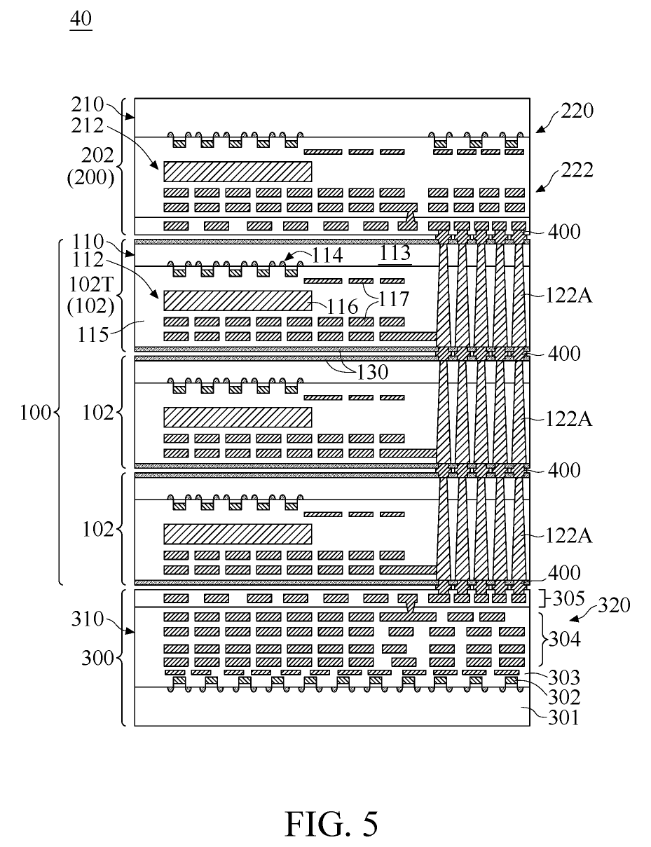

In FIGS. 1, 2A, and 2B, an example is illustrated in which each of the vertical connectors 122 includes the TSVs 124 and the TDVs 126. In other embodiments, in each die, the respective vertically stacked TDVs and TSVs may be replaced with integrated through-via structures, as illustrated in FIG. 5.

FIG. 5 shows a cross-sectional view of a semiconductor device 40 with vertical connectors 122A in accordance with some embodiments. Elements in FIG. 5 that are similar to those in FIG. 1 are labeled with the same reference numbers as in FIG. 1 and may not be described again. In some embodiments, the semiconductor device 40 shown in FIG. 5 is similar to the semiconductor device 10 shown in FIG. 1. However, the vertical connectors 122A of the semiconductor device 40 has a configuration and/or structure different than that of the vertical connectors 122 of the semiconductor device 10.

As shown in FIG. 5, each of the vertical connectors 122A is composed of a single structure that penetrates through both the dielectric layer 115 and the substrate 113 of the first memory die 102, thereby serving the function of both TSV and TDV. In some embodiments, each first memory die 102 may be separately fabricated and prepared with such vertical connectors 122A before undergoing bonding and stacking processes.

In the semiconductor device 40, although the supplemental circuits are illustrated by way of example as supplemental circuits 222 (e.g., power management circuits) in FIGS. 2A and 2B, they may alternatively be implemented as other types of supplemental circuits described in different embodiments, such as the supplemental circuits 222A in FIGS. 3A and 3B, or the supplemental circuits 222B in FIGS. 4A and 4B.

In alternative embodiments, each of the plurality of vertical connectors includes a unitary TDV that extends through the plurality of first memory dies, as illustrated in FIGS. 6A-6E. As used herein, “unitary” may refer to the vertical connector being formed as a single, continuous via that extends through all of the stacked first memory dies, rather than being formed as multiple via segments connected in series.

FIGS. 6A to 6E are schematic diagrams illustrating various stages of a method for manufacturing a semiconductor device 50 in accordance with some embodiments. Elements in FIGS. 6A to 6E that are similar to those in FIG. 1 are labeled with the same reference numbers as in FIG. 1 and may not be described again. In some embodiments, the semiconductor device 50 shown in FIG. 6E is similar to the semiconductor device 10 shown in FIG. 1. However, the semiconductor device 50 has a unitary TDV and the supplemental circuits 222B.

Referring to FIG. 6A, the first and the second memory tiers 100 and 200 are bonded using a dielectric-dielectric (e.g., oxide-oxide) bonding process that includes the following steps. First, the second memory die 202 and a plurality of first memory dies 102A are provided. In some embodiments, the second memory die 202 includes the supplemental circuits 222B as shown in FIGS. 4A and 4B. Each of the first memory dies 102A includes a dielectric-filled structure 150, or called dielectric-filled trench, formed in the first reserved region 120 of the first memory die 102A. The dielectric-filled structure 150 may be formed and extend in a portion of the substrate 113 (e.g., silicon) of the first memory die 102A. In some embodiments, the dielectric-filled structure 150 can be formed by forming a trench at the substrate 113 in the first reserved region 120, and subsequently filling the trench by dielectric materials. In some embodiments, a material of the dielectric-filled structure 150 includes silicon oxide-based material.

Next, one of the first memory dies 102A and the second memory die 202 are arranged to be fusion bonded through contact of a first dielectric bonding layer 502 with a second dielectric bonding layer 504. The first dielectric bonding layer 502 on the first memory die 102A can thus be bonded with the second dielectric bonding layer 504 on the second memory die 202 to form a dielectric bonding structure 500 between the first and the second memory dies 102A and 202. In some embodiments, the first dielectric bonding layer 502 and the second dielectric bonding layer 504 are formed in proximity to the BEOL structure in the first memory die 102A and the second memory die 202, respectively. Thus, the first memory die 102A and the second memory die 202 are bonded in a face-to-face scheme (i.e., F2F bonding). In some embodiments, material of the dielectric bonding layers 502 and 504 include silicon oxide.

In some embodiments, the first memory die 102A can be thinned in a thinning operation to expose the dielectric-filled structure 150 from a surface of the substrate 113. In order to stack more than one first memory die 102A over the second memory die 202, another first dielectric bonding layer 502 can be subsequently formed on the thinned side of the first memory die 102A. This first dielectric bonding layer 502 can be used to further bond with another first dielectric bonding layer 502 of another first memory die 102A. In the example shown in FIG. 6A, each of the adjacent two first memory dies 102A stacked over the second memory die 202 are bonded in a face-to-back scheme (i.e., F2B bonding). By repeating the operation to form the first dielectric bonding layer 502 on the first memory dies 102A for four times, for example, four first memory dies 102A that form the first memory tier 100 can be bonded over the second memory die 202 (second memory tier 200).

Referring to FIG. 6B, a plurality of vertical connectors 122B is formed, wherein each of the vertical connectors 122B extends through the first reserved regions 120 of each of the first memory dies 102A of the first memory tier 100. The vertical connectors 122B extend solely through dielectric material(s). The formation of the vertical connectors 122B may include the following steps. First, a plurality of openings is formed, wherein each of the openings penetrates the dielectric-filled structures 150 and the dielectric layers 115 in each of the first memory dies 102A within the first reserved region 120. The openings also penetrate the first dielectric bonding layers 502 along their extending directions. Next, a barrier layer (not shown) and/or a liner layer (not shown) may be deposited in the openings, after which the openings are filled with a conductive material to form the vertical connectors 122B. The barrier layer and/or liner layer may include, for example, titanium (Ti), titanium nitride (TiN), tantalum (Ta), tantalum nitride (TaN), or combinations thereof. The vertical connectors 122B are electrically coupled to the first memory cells 112 in the first memory tier 100. In some embodiments, the material of the vertical connectors 122B includes copper (Cu), aluminum (Al), tungsten (W), titanium (Ti), titanium nitride (TiN), tantalum (Ta), tantalum nitride (TaN), or the like.

In some embodiments, an end of at least one of the vertical connector 122B lands on a metal layer in the RDL 230 of the second memory tier 200. In some embodiments, the metal layer for the landing of the vertical connector 122B is the uppermost metal layer (Mx) 232 (i.e., the metal layer in proximity to the surface over which the second dielectric bonding layer 504 formed), while a lateral surface of the vertical connector 122B is in contact with a metal layer (Mx) 117x of the first memory cell 112. The vertical connectors 122B may be formed to land on different metal layers in the RDL 230 due to the package design.

Referring to FIG. 6C, a RDL 510 is formed over the first memory tier 100, and an insulating layer 522 with bonding pads 524 is formed on the RDL 510. In some embodiments, another end of at least one vertical connector 122B is exposed at the top surface of the first memory tier 100, which is opposite the second memory tier 200. The vertical connector 122B may be electrically coupled to the RDL 510.

Referring to FIG. 6D, the bottom logic die 300 is stacked on the first memory tier 100 using hybrid bonding. In some embodiments, an insulating layer 526 with bonding pads 528 is first formed on the bottom logic die 300. The bottom logic die 300 and the first memory tier 100 are then bonded through contact between the corresponding bonding pads 524 and 528 and the insulating layers 522 and 526, thereby forming a hybrid bonding structure 520 between the bottom logic die 300 and the first memory tier 100.

Referring to FIG. 6E, the stacked dies are flipped, thereby forming the semiconductor device 50. In the semiconductor device 50, the first and the second memory tiers 100 and 200 are bonded using a dielectric-dielectric bonding process, while the first memory tier 100 and the bottom logic die 300 are bonded using a hybrid bonding process. In other embodiments, the memory tiers 100 and 200 and/or the first memory tier 100 and the bottom logic die 300 may instead be bonded using solder bump bonding, via the conductive connectors 400 shown in FIG. 1, for example.

In summary, the semiconductor device according to the present disclosure includes supplemental circuits formed in the reserved region of the top memory tier. The reserved region may thus be utilized to form supplemental circuits, such as, without limitation, power management circuits, capacitors, or additional memory cells, rather than being reserved solely for vertical connectors. Accordingly, spatial utilization in the top memory tier can be significantly improved, while overall integration efficiency and circuit functionality of the stacked semiconductor device can be enhanced. Moreover, layout waste and parasitic effects can be reduced, and manufacturing cost can be lowered by avoiding the need for additional dies or photomasks.

While the disclosure has been described by way of example and in terms of the preferred embodiments, it should be understood that the disclosure is not limited to the disclosed embodiments. On the contrary, it is intended to cover various modifications and similar arrangements. Therefore, the scope of the appended claims should be accorded the broadest interpretation so as to encompass all such modifications and similar arrangements.

What is claimed is:

1. A semiconductor device, comprising:
a first memory tier comprising a first array region including a first memory cell formed therein, and a first reserved region laterally adjacent to the first array region, wherein the first memory tier further comprises a vertical connector formed in the first reserved region and electrically coupled to the first memory cell; and
a second memory tier disposed on the first memory tier, comprising a second array region including a second memory cell formed therein, and a second reserved region laterally adjacent to the second array region, wherein the second memory tier further comprises supplemental circuits formed in the second reserved region,
wherein the vertical connector extends vertically through the first memory tier ,
wherein the second reserved region of the second memory tier overlaps the first reserved region of the first memory tier.

2. The semiconductor device as claimed in claim 1, wherein the vertical connector is electrically coupled to the supplemental circuits in the second reserved region of the second memory tier.

3. The semiconductor device as claimed in claim 1, wherein the second reserved region of the second memory tier is superimposed on the first reserved region of the first memory tier.

4. The semiconductor device as claimed in claim 1, wherein the first memory tier comprises a plurality of first memory dies stacked on one another, and each of the first memory dies comprises a respective first array region and a respective first reserved region.

5. The semiconductor device as claimed in claim 4, wherein the second memory tier comprises a second memory die stacked over a topmost of the first memory dies, wherein the second memory die comprises the second array region and the second reserved region.

6. The semiconductor device as claimed in claim 1, wherein the first memory tier and the second memory tier are bonded through bumps or a hybrid bonding structure.

7. The semiconductor device as claimed in claim 1, wherein the first and the second memory tiers are bonded through a dielectric-to-dielectric bonding structure.

8. The semiconductor device as claimed in claim 1, further comprising:
a logic die disposed on the first memory tier, wherein the logic die comprises a first region corresponding to the first array region of the first memory tier, and a second region corresponding to the first reserved region of the first memory tier,
wherein the vertical connector is interposed between the second region of the logic die and the second reserved region of the second memory tier.

9. The semiconductor device as claimed in claim 8, wherein the vertical connector electrically couples the first memory cell of the first memory tier to the logic die.

10. The semiconductor device as claimed in claim 1, wherein the vertical connector at least extends through a semiconductor material or a dielectric material of the first memory tier.

11. The semiconductor device as claimed in claim 1, wherein the first and the second memory cells are electrically coupled to the supplemental circuits,
wherein the supplemental circuits are power management circuits configured to regulate or convert power delivered through the vertical connector.

12. The semiconductor device as claimed in claim 1, wherein the supplemental circuits comprise capacitors or inductors.

13. The semiconductor device as claimed in claim 1, wherein the supplemental circuits comprise dynamic-random-access-memory (DRAM) cells that are not electrically connected to the first memory cell and the second memory cell.

14. A semiconductor device, comprising:
a logic die;
a middle memory tier stacked over the logic die, wherein the middle memory tier comprises a plurality of first memory dies stacked on each other, wherein each of the plurality of first memory dies comprises a first array region including a plurality of first memory cells formed therein and a first reserved region laterally adjacent to the first array region; and
a top memory tier stacked over the middle memory tier, wherein the top memory tier comprises a top memory die, wherein the top memory die comprises a top array region and a top reserved region laterally adjacent to the top array region, wherein the top reserved region comprises a plurality of supplemental circuits formed therein and overlaps the first reserved regions of the plurality of first memory dies,
wherein the middle memory tier further comprises a plurality of vertical connectors disposed in the first reserved regions and extending vertically through the plurality of first memory dies.

15. The semiconductor device as claimed in claim 14, wherein the plurality of vertical connectors electrically couples the plurality of first memory cells to the logic die.

16. The semiconductor device as claimed in claim 14, wherein each of the plurality of vertical connectors comprises a unitary through-dielectric via (TDV) that extends through the plurality of first memory dies.

17. The semiconductor device as claimed in claim 14, wherein the top array region of the top memory die comprises a top memory cell formed therein, wherein the plurality of first memory cells and the top memory cell are all dynamic-random-access-memory (DRAM) cells.

18. The semiconductor device as claimed in claim 14, wherein the plurality of first memory dies is fabricated using a first reticle set, and the top memory die is fabricated using a second reticle set that is different from the first reticle set.

19. The semiconductor device as claimed in claim 14, wherein
the top array region comprises DRAM switch transistors, DRAM capacitors electrically coupled to the DRAM switch transistors, and DRAM periphery transistors formed therein; and
the supplemental circuits in the top reserved region comprise additional transistors fabricated by a same process node of the DRAM periphery transistors.

20. The semiconductor device as claimed in claim 14, wherein the supplemental circuits comprise control circuits configured to control signals transmitted through the plurality of vertical connectors.
